(19) United States
(12) Patent Application Publication
(10) Pub. No.: US 2024/0105860 A1
(43) Pub. Date: Mar. 28, 2024

(54) LOW TEMPERATURE VARACTORS USING VARIABLE CAPACITANCE MATERIALS

(71) Applicant: Intel Corporation, Santa Clara, CA (US)

(72) Inventors: Abhishek Anil Sharma, Portland, OR (US); Tahir Ghani, Portland, OR (US); WIlfred Gomes, Portland, OR (US); Anand Murthy, Portland, OR (US); Sagar Suthram, Portland, OR (US); Pushkar Ranade, San Jose, CA (US)

(73) Assignee: Intel Corporation, Santa Clara, CA (US)

(21) Appl. No.: 17/955,235

(22) Filed: Sep. 28, 2022

(51) Int. Cl. H01L 29/93; H01L 21/28; H01L 29/51; H01L 29/66

(52) U.S. Cl. CPC H01L 29/93; H01L 29/40111; H01L 29/516; H01L 29/66174

(57) ABSTRACT

An integrated circuit (IC) die includes a plurality of varactor devices, where at least one varactor of the plurality of varactor devices comprises a first electrode, a second electrode, and a multi-layer stack of ferroelectric material (e.g., ferroelectric variable capacitance material) disposed between the first and second electrodes. Other embodiments are disclosed and claimed.

### BACKGROUND

A varactor refers to a circuit element that is a diode that functions like a variable capacitor. A varactor may also be referred to as a varicap. The PN junction of a varactor may function as the dielectric and plates of a capacitor. There is an ongoing need for improved computational devices to enable ever increasing demand for modeling complex systems, providing reduced computation times, and other considerations. In some contexts, scaling features of integrated circuits has been a driving force for such improvements. Other advancements have been made in materials, device structure, circuit layout, and so on. In particular, there is an ongoing desire to improve varactor device structures that are included in or otherwise support operation of integrated circuits. It is with respect to these and other considerations that the present improvements have been needed. Such improvements may become critical as the desire to improve computational efficiency become even more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIG. 1 illustrates a cross-sectional side view of an example integrated circuit (IC) die;

FIG. 2 illustrates a block diagram of an example of a system;

FIG. 3 illustrates a block diagram of an example of circuit that includes a low temperature varactor using variable capacitance materials;

FIG. 4 is a graph of amplitude of piezoresponse versus voltage;

FIGS. 5A to 5E illustrate cross sectional side views of example varactor devices;

FIG. 6 illustrates a cross sectional side view of an example ferroelectric superlattice;

FIG. 7 illustrates a cross-sectional view of a low-temperature IC system with low temperature varactors using variable capacitance materials, using die- and package-level active cooling;

FIG. 8 illustrates a view of an example two-phase immersion cooling system for low-temperature operation of an IC die;

FIGS. 9A to 9B illustrates various processes or methods for forming low temperature varactors using variable capacitance materials on an IC die;

FIG. 10 illustrates a diagram of an example data server machine employing an IC die with low temperature varactors using variable capacitance materials; and

FIG. 11 is a block diagram of an example computing device, all in accordance with at least some implementations of the present disclosure.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure. The term “aligned” (i.e., vertically or laterally) indicates at least a portion of the components are aligned in the pertinent direction while “fully aligned” indicates an entirety of the components are aligned in the pertinent direction.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking, or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to improve varactors. One problem is that low voltage ferroelectric materials may exhibit a narrow range of capacitance at room temperature. Another problem is that some variable capacitors may create a sharp capacitance change at low temperatures. Without being limited to theory of operation, the sharp capacitance change may be due to lack of fermi level smearing. Some embodiments may overcome one or more of the foregoing problems. Some embodiments may provide technology for low temperature varactors using variable capacitance materials.

Integrated circuit dies, systems, circuits, and techniques are described herein related to varactor devices for ultra-low voltage operation. Such varactor devices may be operable at very low temperatures for improved device performance and/or they may be integrated with complementary metal oxide semiconductor field effect transistors (CMOS FETs) such as FinFETs.

Techniques discussed herein provide advantageous varactor devices for low voltage applications. In some embodiments, such applications are deployed at very low temperatures, such as, at or below 0° C. For example, the varactor devices may be deployed in an integrated circuit (IC) die including or coupled to cooling structure operable to remove heat from the IC die to achieve an operating temperature at the very low temperature. As used herein, the term cooling structure or active cooling structure indicates a device that uses power to provide cooling (e.g., via flow of a coolant, immersion in a coolant, etc.). Notably, the cooling structure or active cooling structure need not be in operation to be labeled as such. The active cooling structure may be part of the IC die, provided separate from the IC die, or both. In some contexts, an active cooling structure is not needed as the IC die is deployed in a very low temperature environment such as in any of a subpolar oceanic climate, a subarctic climate, an arctic climate, a tundra climate, an ice cap climate, or any other environment of sustained cold temperatures.

In some embodiments, a varactor device includes ferroelectric variable capacitance materials. At room temperatures, such materials exhibit only narrow variable capacitor behavior that significantly limits the utility of such materials in a varactor device. However, at very low temperatures, such materials exhibit much wider variable capacitance characteristics. For example, at very low temperatures, a two terminal device may be constructed with suitably selected ferroelectric variable capacitance materials so the device acts as a varactor and may be deployed in a wide variety of useful circuits.

In deployment at very low temperatures, varactor devices using such materials systems have voltage controlled capacitance behavior. Therefore, such varactor devices may advantageously be deployed as various circuits/devices including diodes, tuning diodes, varicap diodes, varactor diodes, variable capacitance diodes, variable reactance diodes, etc. In some embodiments, the varactor devices are used as voltage-controlled capacitor devices at very low voltage. In some implementations, the term very low voltage indicates a voltage of not more than 50 mV, although lower voltages may be used such as voltages of not more than 10 mV. In some embodiments, the varactor devices are integrated with CMOS FETs such as CMOS FinFETs. Notably, after fabrication of the varactor devices over a first substrate, the varactor devices may be layer transferred to a second substrate such as a silicon substrate and the CMOS FETs may be fabricated in an exposed portion of the silicon substrate either on the same side as the varactor devices or on an opposite side of the varactor devices. The varactor devices and CMOS FETs are then integrated into circuits that advantageously use both transistor types at very low temperature. For example, the varactor devices may be deployed as diodes, variable capacitors, etc., and the CMOS FETs may be deployed in other circuitry.

As discussed, an IC die including varactor devices and CMOS FETs may be deployed in a very low temperature context. In some embodiments, the operating temperature of the IC die is maintained at or below 0° C. In some embodiments, the operating temperature of the IC die is maintained at or below about −196° C. (i.e., using liquid nitrogen as the coolant). In some embodiments, the operating temperature of the IC die is maintained at or below about −25° C. In some embodiments, the operating temperature of the IC die is maintained at or below about −50° C. In some embodiments, the operating temperature of the IC die is maintained at or below about −70° C. In some embodiments, the IC die is maintained at or below about −100° C. Other temperatures may be used based on coolant, environment, and so on. Other temperatures may be used based on coolant, environment, and so on. In operation at such very low temperatures, the varactor devices become operable and the CMOS FETs see a substantial boost in performance relative to operation at higher temperatures inclusive of increased carrier mobility, reduced contact resistance, and reduced leakage.

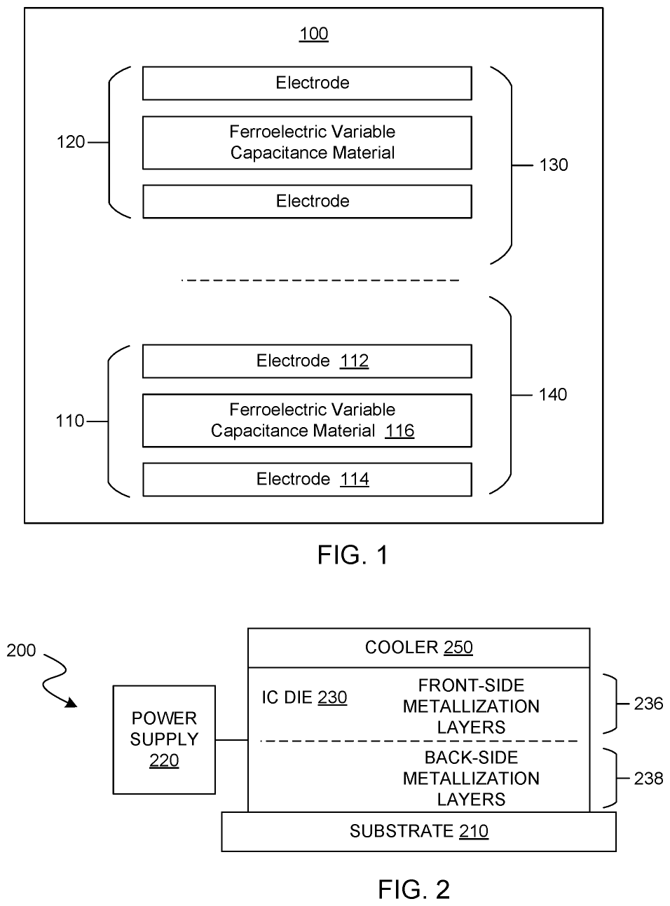

FIG. 1 shows an illustrative cross-sectional side view of an example integrated circuit (IC) 100 that includes varactors in accordance with some embodiments. The IC die 100 includes a plurality of varactor devices (e.g., varactor 110, varactor 120, etc.), where at least one varactor 110 of the plurality of varactor devices comprises a first electrode 112, a second electrode 114, and a multi-layer stack of ferroelectric material 116 (e.g., ferroelectric variable capacitance material) disposed between the first and second electrodes 112, 114. In some embodiments, the ferroelectric material may comprise hysteretic oxide material (e.g., with variable capacitance material characteristics). In some embodiments, the multi-layer stack of hysteretic oxide material may be formed as a ferroelectric superlattice. For example, the ferroelectric superlattice may comprise alternated layers of wide band gap layers and narrow band gap layers.

Some varactor devices may have the first and second electrodes 112, 114 arranged as parallel plate electrodes. Alternatively, or additionally, some varactor devices may have first and second electrodes arranged as interdigitated electrodes. In some embodiments, the IC die 100 may further include front-side layers 130 and back-side layers 140, and the at least one varactor 110 of the plurality of varactor devices may be formed in the back-side layers 140. In some embodiments, the at least one varactor 110 formed in the back-side layers 140 may be configured to operate as a diode.

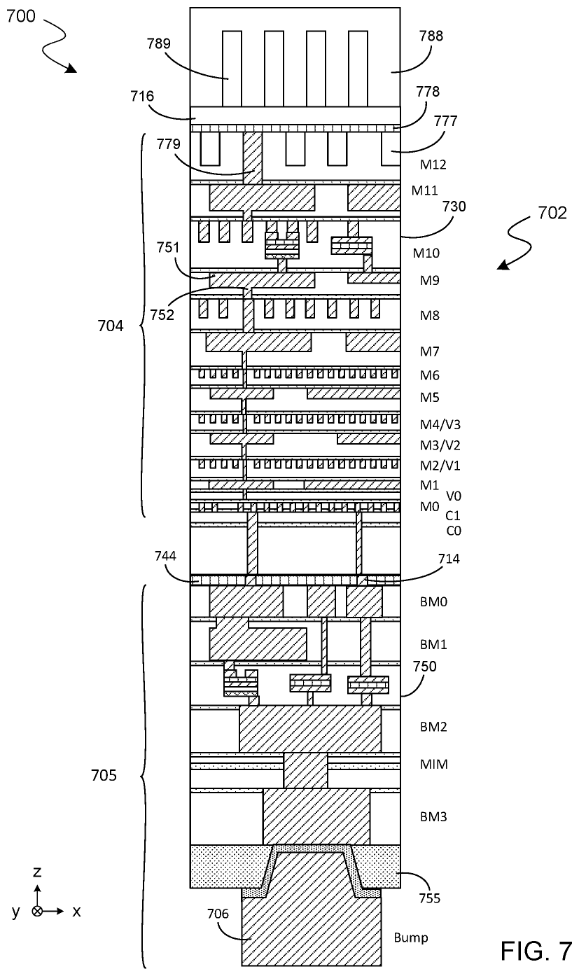

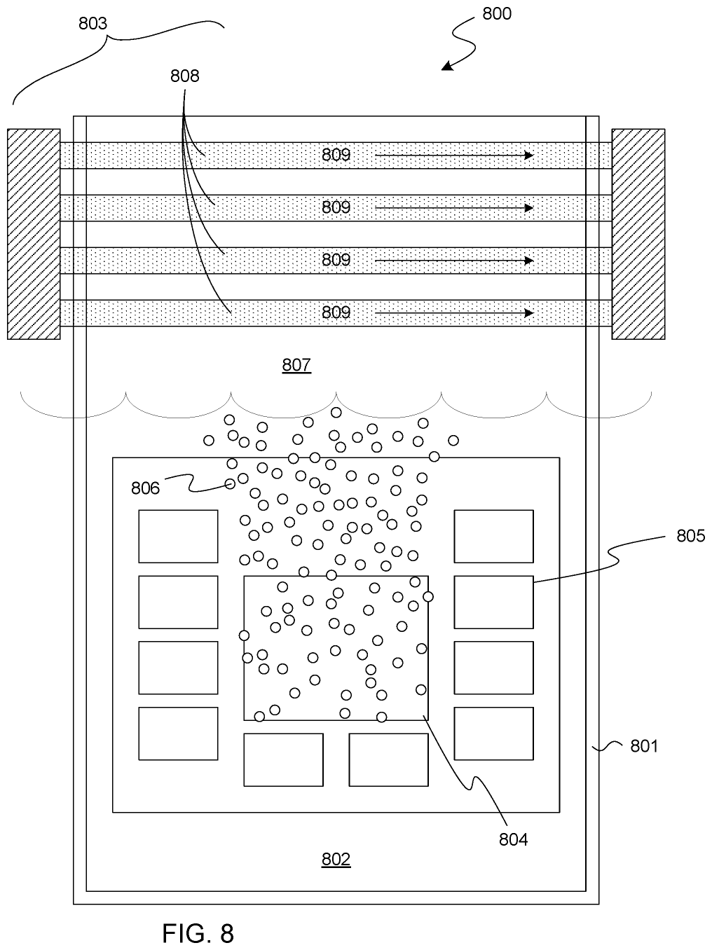

FIG. 2 shows a block diagram view of an example of a system 200 that includes a substrate 210, a power supply 220, and an IC die 230 attached to the substrate 210 and coupled to the power supply 220. The IC die 230 may be similarly configured as any of the various ICs described herein including, for example, the IC die 100 (FIG. 1) and IC die 702 (FIG. 7). Any suitable substrate technology may be utilized for the substrate 210 including, for example, the substrates described herein in connection with FIGS. 7 and 8 (e.g., substrate 805). In some embodiments, the IC die 230 may be coupled to the power supply 220 through the substrate 210.

In some embodiments, the IC die 230 may include a plurality of varactor devices, wherein at least one varactor of the plurality of varactor devices comprises a first electrode, a second electrode, and a multi-layer stack of ferroelectric material (e.g., ferroelectric variable capacitance material) disposed between the first and second electrodes. In some embodiments, the ferroelectric material may comprise hysteretic oxide material (e.g., with variable capacitance material characteristics). In some embodiments, the multi-layer stack of hysteretic oxide material may be formed as a ferroelectric superlattice. For example, the ferroelectric superlattice may comprise alternated layers of wide band gap layers and narrow band gap layers.

Some varactor devices may have the first and second electrodes arranged as parallel plate electrodes. Alternatively, or additionally, some varactor devices may have first and second electrodes arranged as interdigitated electrodes. In some embodiments, the IC die 230 may further include front-side metallization layers 236 and back-side metallization layers 238, and the at least one varactor of the plurality of varactor devices may be formed in the back-side layers 238. In some embodiments, the at least one varactor formed in the back-side layers 238 may be configured to operate as a diode.

The system 200 further includes a cooler 250 thermally coupled to the IC die 230. In some embodiments, the cooler 250 provides a cooling structure operable to remove heat from the IC die to achieve an operating temperature at or below 0° C. For example, the IC die 230 may comprise a plurality of metallization layers over a front side of the plurality of varactor devices, the metallization layers to provide signal routing for the plurality of varactor devices, and the cooling 250 may be over the plurality of metallization layers. In some embodiments, the cooler 250 may comprise a plurality of microchannels in the IC die 230 and over the plurality of metallization layers, the microchannels to convey a heat transfer fluid therein. In some embodiments, the cooler 250 may further comprise a chiller mounted to the IC die 230 over the microchannels, the chiller comprising one of a solid body comprising second microchannels to convey a second heat transfer fluid therein or a heat sink for immersion in a low-boiling point liquid. In some embodiments, the cooler 250 may be operable to remove heat from the IC die to achieve an operating temperature at or below about −25° C. In some embodiments, the cooler 250 may be configured to convey liquid nitrogen to achieve an operating temperature at or below about −196° C.

Suitably configured low temperature varactor devices using variable capacitance materials as described herein may utilized as varicap diodes, varactor diodes, variable capacitance diodes, variable reactance diodes, tuning diodes or other types of diode configured to utilize the voltage-dependent capacitance of a reverse-biased junction. Embodiments of low temperature varactor devices using variable capacitance materials may be utilized as voltage-controlled capacitors in any useful circuitry including, for example, voltage-controlled oscillators, parametric amplifiers, frequency multipliers, etc. A varicap diode may be used a tuned circuit in parallel with any existing capacitance or inductance.

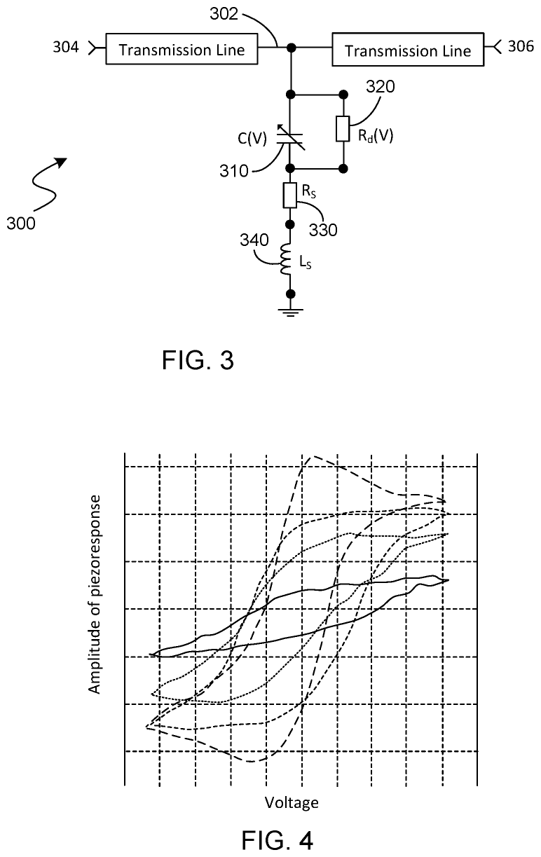

FIG. 3 shows a block diagram of a circuit 300 that includes a varactor according to an embodiment. A transmission line 302 between two points (304, 306) includes a varactor 310 coupled between the transmission line 302 and ground. The varactor 310 may be coupled in parallel with a variable resistor 320. A capacitance C(V) of the varactor 310 and a resistance Rd(V) of the resistor 320 may be controlled by a voltage (V). The transmission line 302 (e.g., and other metallization and dielectric structures associated with the transmission line 302) may exhibit some parasitic inductance Ls, some fixed parasitic resistance Rs, represented in FIG. 3 as resistor 330 and inductor 340.

Having a high capacitance connected to an interconnect line or a metal line in the back-side of an IC die may be associated with higher loading that means that transmission line will be slower. But if that same transmission line is holding power (e.g., a static voltage), then a high capacitance may be beneficial. The varactor 310 provides a variable capacitor such that the transmission line 302 may be re-purposed between power interconnect as well as signal interconnect. With respect to parasitic inductance, the varactor 310 may be used to balance the total impedance to ensure that the resistance, inductance, and capacitance a given frequency are completely balanced to avoid reflections or unwanted signal bounces (e.g., charging and discharging effects on the transmission line 302). The circuit 300 is just an example of a useful circuit for low temperature varactors using variable capacitance material as described herein. Those skilled in the art will appreciate that the low temperature varactors using variable capacitance material described herein may find utility in a wide variety of circuits and scenarios.

FIG. 4 shows an illustrative graph of amplitude of piezoresponse versus voltage for representative ferroelectric variable capacitance materials of different thicknesses and at different operating temperatures. The solid line corresponds to operation at room temperature. As shown in the graph, the material does not exhibit sufficient piezoresponse at room temperature to provide utility as a varactor device (e.g., the capacitance does not change too much as a function of voltage). On the other hand, as shown by the dashed lines, as the thickness of the material increases and the temperature decreases, the material exhibits sufficient piezoresponse at lower temperatures to provide utility as a varactor device (e.g., there is substantial change in capacitance as a function of voltage).

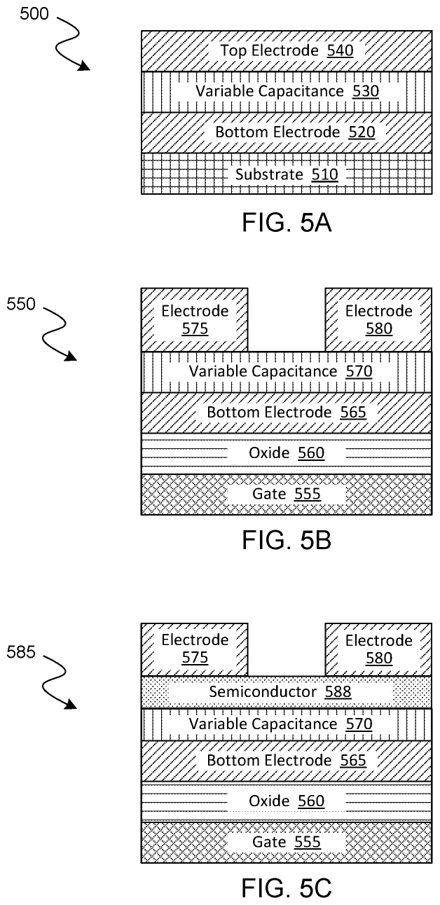

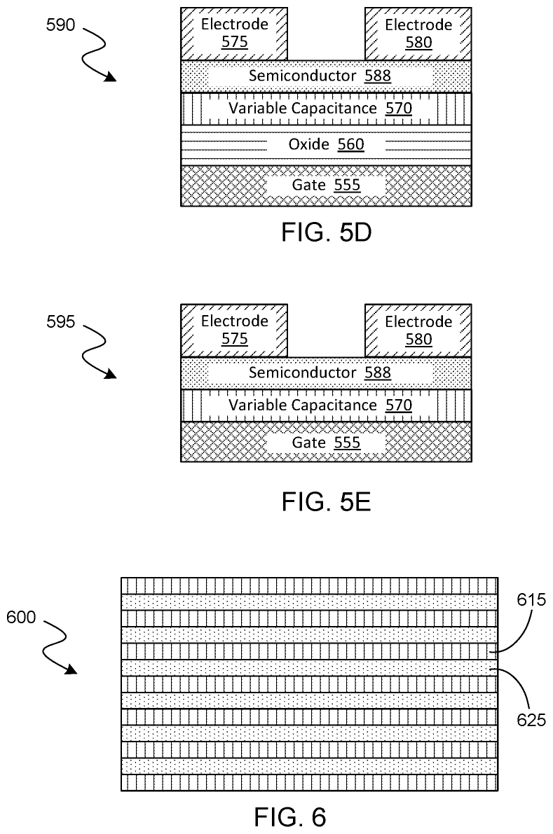

FIG. 5A is a cross-sectional side view of a varactor device 500 according to an embodiment. The device 500 includes a first material 510 (e.g., or stack of materials), a second material 520 (e.g., or stack of materials) over the first material 510, a third material 530 (e.g., or stack of materials) over the second material 520, and a fourth material 540 (e.g., or stack of materials) over the third material 530. In some embodiments, an additional semiconductor layer and oxide layer may be between the second material 520 and the third material 530. Any suitable techniques may be utilized to form, grow, or deposit the materials including, for example, atomic layer deposition (ALD), chemical vapor deposition (CVD), and plasma vapor deposition (PVD).

In some embodiments, the first material 510 may correspond to a substrate (e.g., a silicon substrate), which may further correspond to any number of layers of metallization and/or dielectric material. Example suitable substrate materials include SiOx, SiN, SiON, SiOC, SiC, SrOx, SrTiOx, TiOx, etc.

In some embodiments, the second material 520 may include any metal or semiconductor material suitable to act as a bottom/gate electrode of the device 500. Example suitable electrode materials include TiN, Ti, Ta, TaN, SrTiOx, RuOx and other conducting oxides, W, Cu, CuSex, CuSx, WN, Mo, Co, etc.

In some embodiments, the third material 530 may include hysteretic oxide material suitable to provide the voltage dependent gate oxide/variable capacitance of the device 500. A suitably configured hysteretic oxide multi-layer stacks may operate with an inverse charge-voltage relationship at low temperatures and ultra-low voltages. In some embodiments, ferroelectric materials are selected that exhibit significant hysteretic behavior and a wide variable capacitance range at lower temperatures. The selected ferroelectric materials may be deposited with a thickness and quantity of layers selected to provide a specified amount of capacitance change at a specified operating voltage and temperature (e.g., a large amount of capacitance change at low temperatures). Example suitable ferroelectric variable capacitance materials include barium titanate, strontium titanate, HfOx added to or separate with ZrOx (with doping of La, Sr, Ba, Ca, Zn, In, Ga, etc.), PZT, BaTiOx, etc. In some embodiments, the third material 530 may be configured as a ferroelectric superlattice (e.g., see FIG. 6).

In some embodiments, the fourth material 540 may include any metal or semiconductor material suitable to act as a top electrode of the device 500. Example suitable electrode materials include the same materials as the bottom electrode. The resulting varactor device 500 has a parallel plate structure and acts a two terminal diode at low temperatures and low voltage with Schottky material between the two terminals.

FIG. 5B is cross-sectional side view of another varactor device 550 according to an embodiment. The device 550 includes a first material 555 (e.g., or stack of materials), a second material 560 (e.g., or stack of materials) over the first material 555, a third material 565 (e.g., or stack of materials) over the second material 560, a fourth material 570 (e.g., or stack of materials) over the third material 565, and a fifth material 575 (e.g., or stack of materials) over the fourth material 570, and a sixth material 580 (e.g., or stack of materials) over the fourth material 570. In some embodiments, an additional semiconductor layer and oxide layer may be between the second material 520 and the third material 530. Any suitable techniques may be utilized to form, grow, or deposit the materials including, for example, atomic layer deposition (ALD), chemical vapor deposition (CVD), and plasma vapor deposition (PVD).

In some embodiments, the first material 555 may include any semiconductor material suitable to act as a gate of the device 550. Example suitable gate materials include TiN, Ti, Ta, TaN, SrTiOx, RuOx and other conducting oxides, W, Cu, CuSex, CuSx, WN, Mo, Co, etc.

In some embodiments, the second material 560 may include any oxide material suitable to act as a gate oxide of the device 550. Example suitable gate oxide materials include HfOx added to or separate with ZrOx (with doping of La, Sr, Ba, Ca, Zn, In, Ga, etc.), PZT, BaTiOx, etc.

In some embodiments, the third material 565 may include any metal or semiconductor material suitable to act as a bottom electrode of the device 550. Example suitable electrode materials include TiN, Ti, Ta, TaN, SrTiOx, RuOx and other conducting oxides, W, Cu, CuSex, CuSx, WN, Mo, Co, etc.

In some embodiments, the fourth material 570 may include hysteretic oxide material suitable to provide the voltage dependent variable capacitance of the device 550. A suitably configured hysteretic oxide multi-layer stacks may operate with an inverse charge-voltage relationship at low temperatures and ultra-low voltages. In some embodiments, ferroelectric materials are selected that exhibit significant hysteretic behavior and a wide variable capacitance range at lower temperatures. The selected ferroelectric materials may be deposited with a thickness and quantity of layers selected to provide a specified amount of capacitance change at a specified operating voltage and temperature (e.g., a large amount of capacitance change at low temperatures). Example suitable ferroelectric variable capacitance materials include barium titanate, strontium titanate, HfOx added to or separate with ZrOx (with doping of La, Sr, Ba, Ca, Zn, In, Ga, etc.), PZT, BaTiOx, etc. In some embodiments, the fourth material 570 may be configured as a ferroelectric superlattice (e.g., see FIG. 6).

In some embodiments, the fifth material 575 and sixth material 580 may include any metal or semiconductor material suitable to act as interdigitated electrodes of the device 550. Example suitable electrode materials include the same materials as the bottom electrode. The resulting varactor device 550 has an interdigitated structure and acts a three terminal transistor. In some embodiments, the gate terminal of the transistor is shorted to either the source or drain terminal such that the varactor device 550 then acts as a two terminal diode at low temperatures and low voltage with Schottky material between the two terminals.

FIG. 5C is cross-sectional side view of another varactor device 585 according to an embodiment. The device 585 includes a seventh material 588 between the fourth material 570 and the fifth and sixth materials 575, 580. The seventh material 588 may include a semiconductor layer. Example suitable materials for the seventh material 588 include InOx, ZnOx, ZnN, GaN, SiC, GaOx, IGZO, ITO, ZTO, IZO, transition metal dichalcogenides like MoS2, WSe2, [poly-Si, poly-Ge, poly-III-V, poly SiGe etc] and single crystal versions of the same, etc.

FIG. 5D is cross-sectional side view of another varactor device 590 according to an embodiment. The device 585 includes the seventh material 588 between the fourth material 570 and the fifth and sixth materials 575, 580, but omits the third material 565.

FIG. 5E is cross-sectional side view of another varactor device 590 according to an embodiment. The device 585 includes the seventh material 588 between the fourth material 570 and the fifth and sixth materials 575, 580, but omits the second and third materials 560, 565.

FIG. 6 is a cross-sectional side view of a ferroelectric superlattice 600 according to an embodiment. The energy required for electrons and holes to transition from the valence band to the conduction band is called a band gap. The band gap of material is measured in units of electron volt (eV). A material with a large eV value may be referred to as a wide band gap material. Conversely, a material with a small eV value may be referred to as a narrow band gap material. The superlattice 600 includes alternating layers of narrow band gap material 615 and wide band gap material 625. The narrow band gap material 615 provides a high variable capacitance aspect of the varactor device (e.g., with more leakage). The wide band gap material 625 provides a leakage control aspect of the varactor device (e.g., a low leakage material for current blocking). The wide band gap material 625 also provides a template layer for the narrow band gap material 615 be deposited/grown.

In some embodiments, the band gap(s) may be modulated by the selected materials for each layer, a selected number of layers, and a selected thickness of each layer to achieve a desired amount of variable capacitance. In some embodiments, other characteristics of the materials, such as dielectric constant, may be modulated to achieve a desired amount of variable capacitance. For the example superlattice 600, a narrow band gap material may be 2 eV or less and a wide band gap material may be more than 2 eV. Suitable examples of materials for the narrow band gap layers include barium titanate (BaTiO3), (K, Ba)(Nb, Ni)O3-δ, Bi(Fe0.5Cr0.5)O3, and (K, Na, Ba)(Nb, Ni)O3-δ (e.g., KNBNNO), etc. Suitable examples of materials for the wide band gap layers include strontium titanate (SrTiO3), HfOx added to or separate with ZrOx (with doping of La, Sr, Ba, Ca, Zn, In, Ga, etc.), PZT, etc.

In some embodiments, ICs with varactors using low voltage ferroelectric variable capacitance materials may be integrated into a low-temperature system. Lower temperatures enhance conduction in many materials and can enable the use of, e.g., different materials and structures (such as smaller transistor channels). A number of structures may be used to lower the system temperature and so allow for the use of, e.g., smaller conducting structures. Active cooling structures can be used to lower system temperatures to below ambient temperature, even to well below ambient temperature. Active cooling structures can include thermoelectric coolers. In some embodiments, active cooling structures include stacks of alternating p- and n-type semiconductor materials. In some embodiments, active cooling structures flow cooling fluids through channels, including microchannels, thermally coupled to IC packages. In some embodiments, active cooling structures include channels thermally coupled to IC dies 100, 230, 702. In some embodiments, active cooling structures include channels on one or more sides of IC dies 100, 230, 702. In some embodiments, active cooling structures include channels within IC dies 100, 230, 702. In some embodiments, active cooling structures include two-phase cooling. In some embodiments, active cooling structures include low-boiling-point fluids. In some embodiments, active cooling structures include refrigerants as cooling fluids. In some embodiments, active cooling structures lower system temperatures to below 0° C.

FIG. 7 illustrates a cross-sectional view of a low-temperature IC system 700 using die- and package-level active cooling, that includes varactors using low voltage ferroelectric variable capacitance materials in accordance with some embodiments. In the example of IC system 700, IC die 702 includes active-cooling structures or components as provided by both die-level microchannels 777 and package-level active-cooling structure 788. IC system 700 includes a lateral surface along the x-y plane that may be defined or taken at any vertical position of IC system 700. The lateral surface of the x-y plane is orthogonal to a vertical or build-up dimension as defined by the z-axis. In some embodiments, IC system 700 may be formed from any substrate material suitable for the fabrication of transistor circuitry. In some embodiments, a semiconductor substrate is used to manufacture varactors and other transistors and components of IC system 700. The semiconductor substrate may include a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials, such as gallium arsenide. The substrate may also include semiconductor materials, metals, dielectrics, dopants, and other materials commonly found in semiconductor substrates.

In FIG. 7, IC system 700 includes an IC die 702, which is a monolithic IC with varactors using low voltage ferroelectric variable capacitance materials as described herein, including front-side metallization layers 704 (or front-side interconnect layers), and optional back-side metallization layers 705 (or back-side interconnect layers). As shown, IC die 702 may include varactors using low voltage ferroelectric variable capacitance materials embedded within front-side layers 730 and/or back-side layers 750 (the detailed structure of the varactors is omitted from the cross-section of FIG. 7 to avoid obscuring the figure). In some embodiments, front-side metallization layers 704 (including further varactors using low voltage ferroelectric variable capacitance materials) provide signal routing to the non-planar transistors and back-side metallization layers 705 provide power delivery, as enabled by through-contacts 714, and vias. In some embodiments, IC system 700 further includes a package-level cooling structure 788, which may be deployed on or over front-side metallization layers 704 (as shown) or on or over a back-side of IC die 702. In some embodiments, package-level cooling structure 788 is coupled to IC die 702 by an adhesion layer 716. IC system 700 may also be deployed without back-side metallization layers 705 shown in FIG. 7. In such embodiments, signal routing and power are provided to circuits of the IC die 702 via front-side metallization layers 704. However, use of back-side metallization layers 705 may offer advantages.

The circuits of the IC die 702 are connected and thermally coupled by metallization, e.g., metal heat spreader 744, to the entire metallization structure by through-contacts 714. In this way, circuits of the IC die 702 are thermally coupled to both the die-level active-cooling structures (of die-level microchannels 777) and package-level active-cooling structure 788.

Interconnectivity of transistors, signal routing to and from circuitry of the IC die 702, vias 752 (e.g., and other vias), etc., power delivery to circuitry of the IC die 702, etc., and routing to an outside device (not shown), is provided by front-side metallization layers 704, optional back-side metallization layers 705, and package-level interconnects 706. In the example of FIG. 7, package-level interconnects 706 are provided on or over a back-side of IC die 702 as bumps over a passivation layer 755, and IC system 700 is attached to a substrate (and coupled to signal routing to, power delivery, etc.) by package-level interconnects 706. However, package-level interconnects 706 may be provided using any suitable interconnect structures such as bond pads, solder bumps, etc. Furthermore, in some embodiments, package-level interconnects 706 are provided on or over a front-side of IC die 702 (i.e., over front-side metallization layers 704) and package-level cooling structure 788 is provided on or over a back-side of IC die 702.

In IC system 700, IC die 702 includes die-level, active-cooling as provided by die-level microchannels 777. Die-level microchannels 777 are to convey a heat transfer fluid therein to remove heat from IC die 702. The heat transfer fluid may be any suitable liquid or gas. In some embodiments, the heat transfer fluid is liquid nitrogen operable to lower the temperature of IC die 702 to a temperature at or below about −196° C. In some embodiments, the heat transfer fluid is a fluid with a cryogenic temperature operating window (e.g., about −180° C. to about −70° C.). In some embodiments, the heat transfer fluid is one of helium-3, helium-4, hydrogen, neon, air, fluorine, argon, oxygen, or methane.

As used herein, the term “microchannels” indicates a channel to convey a heat transfer fluid with the multiple microchannels providing discrete separate channels or a network of channels. Notably, the plural microchannels does not indicate separate channel networks are needed. Such die-level microchannels 777 may be provided in any pattern in the x-y plane such as serpentine patterns, patterns of multiple parallel die-level microchannels 777, or the like. Die-level microchannels 777 couple to a heat exchanger (not shown) that removes heat from and cools the heat transfer fluid before re-introduction to die-level microchannels 777. The flow of fluid within die-level microchannels 777 may be provided by a pump or other fluid flow device. The operation of the heat exchanger, pump, etc. may be controlled by a controller.

In the illustrated embodiment, die-level microchannels 777 are implemented at metallization level M12. In other embodiments, die-level microchannels 777 are implemented over metallization level M12. Die-level microchannels 777 may be formed using any suitable technique or techniques such as patterning and etch techniques to form the void structures of die-level microchannels 777 and passivation or deposition techniques to form a cover structure 778 to enclose the void structures. As shown, in some embodiments, the die-level, active-cooling structure of IC system 700 includes a number of die-level microchannels 777 in IC die 702 and over a number of front-side metallization layers 704. As discussed, die-level microchannels 777 are to convey a heat transfer fluid therein. In some embodiments, a metallization feature 779 of metallization layer M12 is laterally adjacent to die-level microchannels 777. For example, metallization feature 779 may couple to a package-level interconnect structure (not shown) for signal routing for IC die 702. In some embodiments, a passive heat removal device such as a heat sink or the like may be used instead of or in addition to package-level cooling structure 788. In some embodiments, package-level cooling structure 788 is not deployed in IC system 700.

As used herein, the term “metallization layer” describes layers with interconnections or wires that provide electrical routing, generally formed of metal or other electrically and thermally conductive material. Adjacent metallization layers may be formed of different materials and by different methods. Adjacent metallization layers, such as metallization interconnects 751, are interconnected by vias, such as vias 752, that may be characterized as part of the metallization layers or between the metallization layers. As shown, in some embodiments, front-side metallization layers 704 are formed over and immediately adjacent transistors. The back-side is then the opposite side, which may be exposed during processing by attaching the front-side to a carrier wafer and exposing the back-side (e.g., by back-side grind or etch operations) as known in the art.

In the illustrated example, front-side metallization layers 704 include M0, V0, M1, M2/V1, M3/V2, M4/V3, and M4-M12. However, front-side metallization layers 704 may include any number of metallization layers such as eight or more metallization layers. Similarly, back-side metallization layers 705 include BM0, BM1, BM2, and BM3. However, back-side metallization layers 705 may include any number of metallization layers such as two to five metallization layers. Front-side metallization layers 704 and back-side metallization layers 705 are embedded within dielectric materials. Furthermore, optional metal-insulator-metal (MIM) devices such as diode devices may be provided within back-side metallization layers 705. Other devices such as capacitive memory devices may be provided within front-side metallization layers 704 and/or back-side metallization layers 705.

IC system 700 includes package-level active-cooling structure 788 having package-level microchannels 789. Package-level microchannels 789 are to convey a heat transfer fluid therein to remove heat from IC die 702. The heat transfer fluid may be any suitable liquid or gas as discussed with respect to die-level microchannels 777. Package-level microchannels 789 may be provided in any pattern in the x-y plane such as serpentine patterns, patterns of multiple parallel package-level microchannels 789, etc. Package-level microchannels 789 couple to a heat exchanger (not shown) that removes heat from and cools the heat transfer fluid before re-introduction to package-level microchannels 789. The flow of fluid within package-level microchannels 789 may be provided by a pump or other fluid-flow device. The operation of the heat exchanger, pump, etc. may be controlled by a controller. In the illustrated embodiment, package-level active-cooling structure 788 is a chiller mounted to IC die 702 such that the chiller has a solid body having microchannels therein to convey a heat transfer fluid.

In some embodiments, the heat-removal fluid deployed in die-level microchannels 777 and package-level active-cooling structure 788 are coupled to the same pump and heat exchanger systems. In such embodiments, the heat removal fluid conveyed in both die-level microchannels 777 and package-level active-cooling structure 788 are the same material. Such embodiments may advantageously provide simplicity. In other embodiments, the heat removal fluids are controlled separately. In such embodiments, the heat removal fluids conveyed by die-level microchannels 777 and package-level active-cooling structure 788 may be the same or they may be different. Such embodiments may advantageously provide improved flexibility.

As discussed, IC system 700 includes IC die 702 and optional die-level and package-level active-cooling structures operable to remove heat from IC die 702 to achieve a very low operating temperature of IC die 702. As used herein, the term “very low operating temperature” indicates a temperature at or below 0° C., although even lower temperatures such as an operating temperature at or below −50° C., an operating temperature at or below −70° C., an operating temperature at or below −100° C., an operating temperature at or below −180° C., or an operating temperature at or below −196° C. may be used. In some embodiments, the operating temperature is in a cryogenic temperature operating window (e.g., about −180° C. to about −70° C.). The active-cooling structure may be provided as a package-level structure (i.e., separable from IC die 702), as a die-level structure (i.e., integral to IC die 702), or both. In some embodiments, IC die 702 is deployed in a cold environment, formed using sufficiently conductive materials, etc. and an active-cooling structure is not used.

FIG. 8 illustrates a view of an example two-phase immersion cooling system 800 for low-temperature operation of an IC die, in accordance with some embodiments. As shown, two-phase immersion cooling system 800 includes a fluid containment structure 801, a low-boiling point liquid 802 within fluid containment structure 801, and a condensation structure 803 at least partially within fluid containment structure 801. As used herein, the term “low-boiling point liquid” indicates a liquid having a boiling point in the very low temperature ranges discussed. In some embodiments, the low-boiling point liquid is one of helium-3, helium-4, hydrogen, neon, air, fluorine, argon, oxygen, or methane.

In operation, a heat generation source 804, such as an IC package including any of IC dies or systems 100, 200, 700 as discussed herein is immersed in low-boiling point liquid 802. In some embodiments, IC dies or systems 100, 200, 700 as deployed in two-phase immersion cooling system 800 do not include additional active cooling structures, although such die-level or package-level active cooling structures may be used in concert with two-phase immersion cooling system 800. In some embodiments, when deployed in two-phase immersion cooling system 800, package-level active-cooling structure 788 is a heat sink, a heat dissipation plate, a porous heat dissipation plate or the like.

Notably, IC die 702 (or IC die 100, 230), is the source of heat in the context of two-phase immersion cooling system 800. For example, IC die 702 may be packaged and mounted on electronics substrate 805. Electronic substrate 805 may be coupled to a power supply (not shown) and may be partially or completely submerged in low-boiling point liquid 802.

In operation, the heat produced by heat generation source 804 vaporizes low-boiling point liquid 802 as shown in vapor or gas state as bubbles 806, which may collect, due to gravitational forces, above low-boiling point liquid 802 as a vapor portion 807 within fluid containment structure 801. Condensation structure 803 may extend through vapor portion 807. In some embodiments, condensation structure 803 is a heat exchanger having a number of tubes 808 with a cooling fluid (i.e., a fluid colder than the condensation point of vapor portion 807) shown by arrows 809 that may flow through tubes 808 to condense vapor portion 807 back to low-boiling point liquid 802. In the IC system of FIG. 8, package-level active-cooling structure 788 includes a passive cooling structure such as a heat sink for immersion in low-boiling point liquid 802.

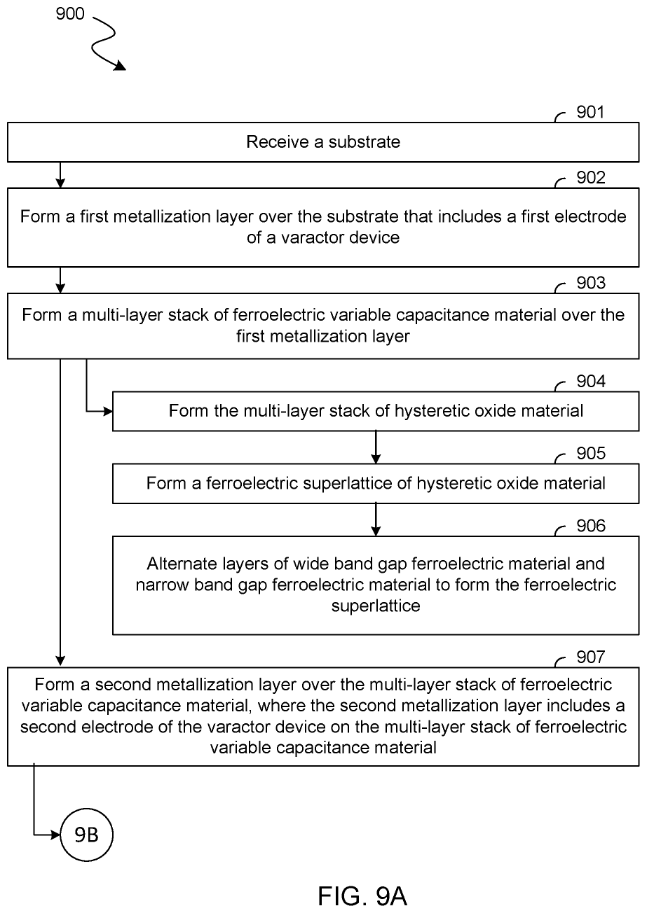

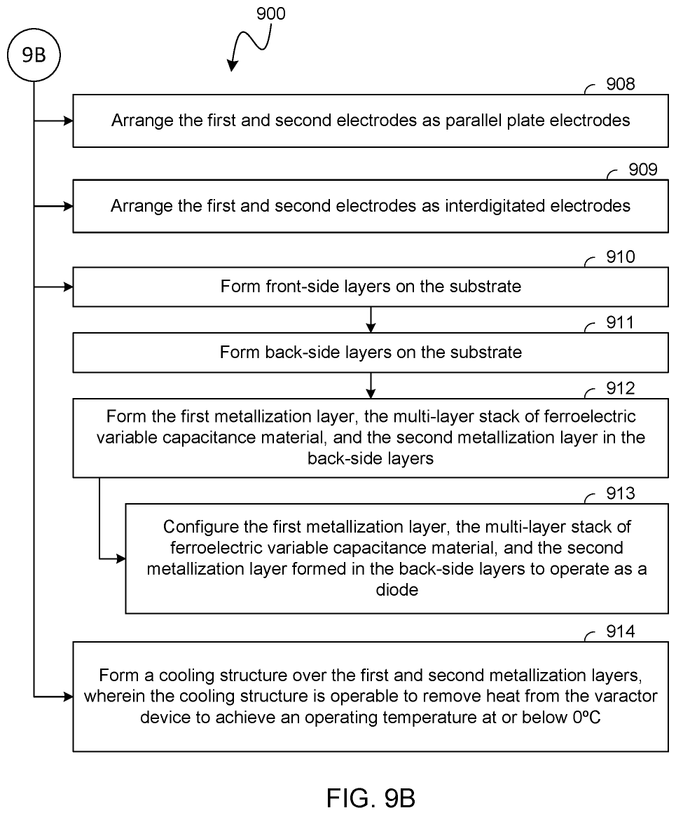

FIGS. 9A to 9B illustrate various processes or methods 900 for forming varactors on an IC die, in accordance with some embodiments. FIGS. 9A to 9B show methods 900 that includes operations 901-914. Some operations shown in FIGS. 9A to 9B are optional. FIGS. 9A to 9B show an example sequence, but the operations can be done in other sequences as well, and some operations may be omitted. Some operations can also be performed multiple times before other operations are performed. Some operations may be included within other operations. Methods 900 generally entail forming varactors using variable capacitance materials.

In operation 901, a substrate is received. The substrate is a planar platform and may already include dielectric and metallization structures. The substrate may be one of many layers in an IC die, and may itself have many layers. The substrate may be above other layers in the IC die (all or of a portion of which may be subsequently removed in back-side metallization contexts), and other layers may subsequently be formed in or over the substrate. In some embodiments, varactors will be formed on a frontside of the substrate. In some embodiments, varactors will be formed on a backside. In some embodiments, varactors will be formed on both sides.

The substrate may include any suitable material or materials. Any suitable semiconductor or other material can be used. Transistors in the IC die may be of the same material as the substrate or, e.g., deposited on the substrate. The substrate may include a semiconductor material that transistors can be formed out of and on, including a crystalline material. In some examples, the substrate may include monocrystalline silicon (Si), germanium (Ge), silicon germanium (SiGe), a III-V alloy material (e.g., gallium arsenide (GaAs)), a silicon carbide (SiC), a sapphire (Al2O₃), or any combination thereof. In some embodiments, the substrate includes crystalline silicon and subsequent components are also silicon.

In operation 902, a first metallization layer is formed over the substrate that includes a first electrode of a varactor device. The first metallization layer need not be formed before, e.g., other layers of the IC die. Forming the first metallization layer and other layers of the IC die may include forming transistors, resistors, and interconnections, e.g., between them and with external structures, including power, signal, data, ground, etc. lines. At least some of these structures may be conventional and known methods may be used.

Transistors in the IC die can be formed from the same material as the substrate or, e.g., deposited on the substrate. In some embodiments, the substrate is crystalline silicon and transistors in the first layer are formed by etching back the substrate to form transistor structures, e.g., non-planar structures, such as fins for access transistor channels. In some embodiments, transistors comprise polycrystalline silicon, which may be deposited over other materials. Other semiconductor materials may be deposited as well, on the substrate or over other structures on the substrate. Such semiconductor materials can be any material suitable for forming a transistor channel, e.g., for an access transistor, but some materials will be preferred for their manufacturing properties, e.g., the capability to be deposited easily, in a well-controlled manner, and in thin layers.

Forming the transistors may include forming ultrathin structures, such as nanowires, nanoribbons, or nanosheets, for transistor channels. In some embodiments, one or a few monolayers of semiconductor materials are deposited over the substrate or other structures. In some embodiments, less than 2 nm of semiconductor material is deposited as a film. In some embodiments, a transition-metal dichalcogenide (TMD) material is deposited to form access transistors. TMDs can be 2D materials, e.g., forming monolayers of semiconductor materials. 2D materials may be deposited on structures, such as backbone features, deposited on the substrate.

The methods for forming transistors may vary with transistor function. TFTs for use as pull-up transistors may be formed as parasitic devices deposited over other structures in some layers. In some embodiments, forming transistors includes depositing amorphous or polycrystalline metal oxides. In some embodiments, a thin, metal-oxide film is deposited that may be semiconducting substantially as-deposited, and/or following some subsequent activation process, such as a thermal anneal.

Other structures, e.g., resistors and metallization, may also be deposited or otherwise formed from such materials, and such forming may be done throughout the forming operations of transistors and other structures. Pull-up resistors may be formed from the substrate material or, e.g., by depositing polycrystalline silicon or other material over the substrate. Other structures, e.g., access transistor gate electrodes, may be formed such that convenient connections can be made to associated structures in the first layer. Metallization may be formed before and after, and interleaved throughout, the forming of other structures.

In operation 903, a multi-layer stack of ferroelectric variable capacitance material is formed over the first metallization layer. For example, the ferroelectric variable capacitance material is formed in or on the substrate and in a layer vertically adjacent the first electrode. The ferroelectric variable capacitance material may be formed after the first metallization layer. Structures in the multi-layer stack of ferroelectric variable capacitance material may be deposited or grown over the top of the first metallization layer. Structures formed, e.g., etched, from a front side of the substrate may be formed, e.g., etched, from a back side of the substrate in another layer. Layouts may be duplicated or mirrored as suits an embodiment. Some embodiments of the method 900 may further include forming an additional semiconductor and oxide layer on the first metallization layer prior to forming the multi-layer stack of ferroelectric variable capacitance material.

In operation 904, the multi-layer stack is formed of hysteretic oxide material. In operation 905, a ferroelectric superlattice is formed of hysteretic oxide material. In operation 906, layers of wide band gap ferroelectric material and narrow band gap ferroelectric material are alternated to form the ferroelectric superlattice.

In operation 907, a second metallization layer is formed over the multi-layer stack of ferroelectric variable capacitance material, where the second metallization layer includes a second electrode of the varactor device on the multi-layer stack of ferroelectric variable capacitance material. For example, the second electrode is formed in or on the substrate and in a layer vertically adjacent the multi-layer stack of ferroelectric variable capacitance material. The second electrode may be formed after the multi-layer stack of ferroelectric variable capacitance material. Structures in the second metallization layer may be deposited or grown over the top of the multi-layer stack of ferroelectric variable capacitance material. In operation 905, the multi-layer stack is formed of hysteretic oxide material. In operation 906,

In operation 908, the first and second electrodes are arranged as parallel plate electrodes. In operation 909, the first and second electrodes are arranged as interdigitated electrodes.

In operation 910-912, front-side layers are formed on the substrate (at 910), back-side layers are formed on the substrate (at 911), and the first metallization layer, the multi-layer stack of ferroelectric variable capacitance material, and the second metallization layer are formed in the back-side layers. At operation 913, the first metallization layer, the multi-layer stack of ferroelectric variable capacitance material, and the second metallization layer formed in the back-side layers are configured to operate as a diode.

At operation 914, a cooling structure is formed over the first and second metallization layers, wherein the cooling structure is operable to remove heat from the varactor device to achieve an operating temperature at or below 0° C.

In some embodiments, two circuits or signals (and more) are formed in vertically adjacent layers where in different metallization layers are connected between layers by forming a vertical metallization structure, e.g., a metallized via connection, on one side of the layers, beyond the horizontal edges or boundaries of the circuits. In some such embodiments, a deep border via connects the different metallization layers. In some embodiments, two of these connected circuits are vertically aligned, and other connected circuits in both layers are not vertically aligned. The vertical metallization structure, e.g., a via, can be formed as part of traditional or other methods, e.g. single or dual damascene techniques, etc.

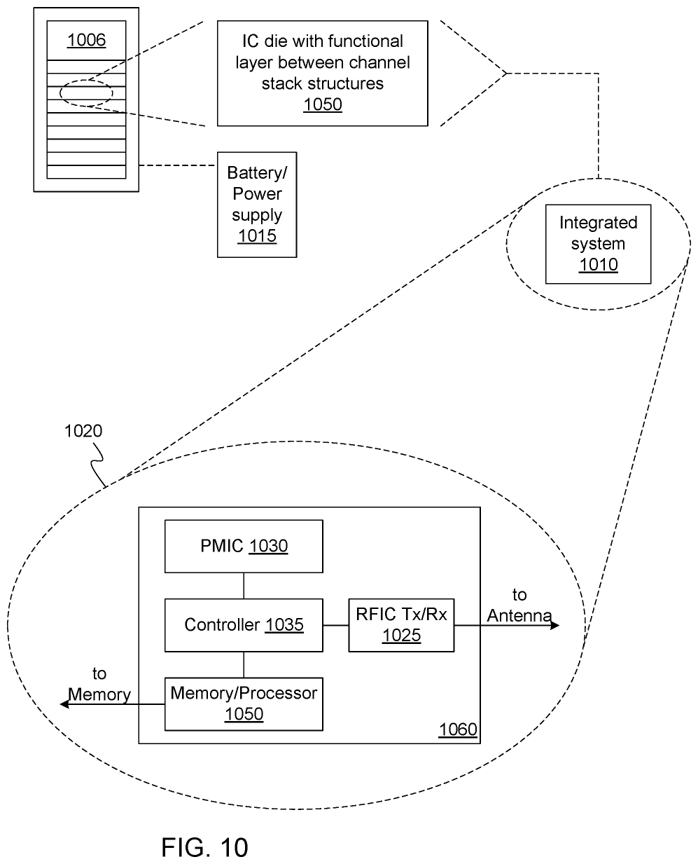

FIG. 10 illustrates a diagram of an example data server machine 1006 employing an IC die with varactors using low voltage ferroelectric variable capacitance materials, in accordance with some embodiments. Server machine 1006 may be any commercial server, for example, including any number of high-performance computing platforms disposed within a rack and networked together for electronic data processing, which in the exemplary embodiment includes one or more devices 1050 having varactors using low voltage ferroelectric variable capacitance materials.

Also as shown, server machine 1006 includes a battery and/or power supply 1015 to provide power to devices 1050, and to provide, in some embodiments, power delivery functions such as power regulation. Devices 1050 may be deployed as part of a package-level integrated system 1010. Integrated system 1010 is further illustrated in the expanded view 1020. In the exemplary embodiment, devices 1050 (labeled “Memory/Processor”) includes at least one memory chip (e.g., RAM), and/or at least one processor chip (e.g., a microprocessor, a multi-core microprocessor, or graphics processor, or the like) having the characteristics discussed herein. In an embodiment, device 1050 is a microprocessor including a cache memory. As shown, device 1050 may be a multi-chip module employing one or more IC dies with varactors using low voltage ferroelectric variable capacitance materials, as discussed herein. Device 1050 may be further coupled to (e.g., communicatively coupled to) a board, an interposer, or a substrate 1060 along with, one or more of a power management IC (PMIC) 1030, RF (wireless) IC (RFIC) 1025, including a wideband RF (wireless) transmitter and/or receiver (TX/RX) (e.g., including a digital baseband and an analog front end module further comprises a power amplifier on a transmit path and a low noise amplifier on a receive path), and a controller 1035 thereof. In some embodiments, RFIC 1025, PMIC 1030, controller 1035, and device 1050 include IC dies having varactors using low voltage ferroelectric variable capacitance materials on substrate 1060 in a multi-chip module.

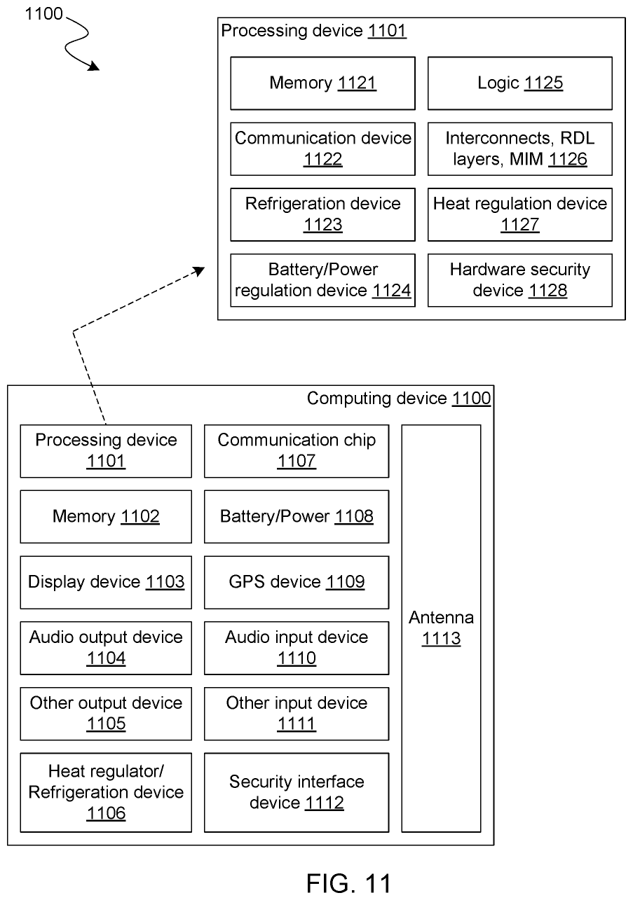

FIG. 11 is a block diagram of an example computing device 1100, in accordance with some embodiments. For example, one or more components of computing device 1100 may include any of the devices or structures discussed herein. A number of components are illustrated in FIG. 11 as being included in computing device 1100, but any one or more of these components may be omitted or duplicated, as suitable for the application. In some embodiments, some or all of the components included in computing device 1100 may be attached to one or more printed circuit boards (e.g., a motherboard). In some embodiments, various ones of these components may be fabricated onto a single system-on-a-chip (SoC) die. Additionally, in various embodiments, computing device 1100 may not include one or more of the components illustrated in FIG. 11, but computing device 1100 may include interface circuitry for coupling to the one or more components. For example, computing device 1100 may not include a display device 1103, but may include display device interface circuitry (e.g., a connector and driver circuitry) to which display device 1103 may be coupled. In another set of examples, computing device 1100 may not include an audio output device 1104, other output device 1105, global positioning system (GPS) device 1109, audio input device 1110, or other input device 1111, but may include audio output device interface circuitry, other output device interface circuitry, GPS device interface circuitry, audio input device interface circuitry, audio input device interface circuitry, to which audio output device 1104, other output device 1105, GPS device 1109, audio input device 1110, or other input device 1111 may be coupled.

Computing device 1100 may include a processing device 1101 (e.g., one or more processing devices). As used herein, the term “processing device” or “processor” indicates a device that processes electronic data from registers and/or memory to transform that electronic data into other electronic data that may be stored in registers and/or memory. Processing device 1101 may include a memory 1121, a communication device 1122, a refrigeration device 1123, a battery/power regulation device 1124, logic 1125, interconnects 1126 (i.e., optionally including redistribution layers (RDL) or metal-insulator-metal (MIM) devices), a heat regulation device 1127, and a hardware security device 1128.

Processing device 1101 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 1100 may include a memory 1102, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1102 includes memory that shares a die with processing device 1101. This memory may be used as cache memory and may include embedded dynamic random-access memory (eDRAM) or spin transfer torque magnetic random-access memory (STT-M RAM).

Computing device 1100 may include a heat regulation/refrigeration device 1106. Heat regulation/refrigeration device 1106 may maintain processing device 1101 (and/or other components of computing device 1100) at a predetermined low temperature during operation. This predetermined low temperature may be any temperature discussed herein.

In some embodiments, computing device 1100 may include a communication chip 1107 (e.g., one or more communication chips). For example, the communication chip 1107 may be configured for managing wireless communications for the transfer of data to and from computing device 1100. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 1107 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1107 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network.

Communication chip 1107 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1107 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1107 may operate in accordance with other wireless protocols in other embodiments. Computing device 1100 may include an antenna 1113 to facilitate wireless communications and/or to receive other wireless communications (such as AM or FM radio transmissions).

In some embodiments, communication chip 1107 may manage wired communications, such as electrical, optical, or any other suitable communication protocols (e.g., the Ethernet). As noted above, communication chip 1107 may include multiple communication chips. For instance, a first communication chip 1107 may be dedicated to shorter-range wireless communications such as Wi-Fi or Bluetooth, and a second communication chip 1107 may be dedicated to longer-range wireless communications such as GPS, EDGE, GPRS, CDMA, WiMAX, LTE, EV-DO, or others. In some embodiments, a first communication chip 1107 may be dedicated to wireless communications, and a second communication chip 1107 may be dedicated to wired communications.

Computing device 1100 may include battery/power circuitry 1108. Battery/power circuitry 1108 may include one or more energy storage devices (e.g., batteries or capacitors) and/or circuitry for coupling components of computing device 1100 to an energy source separate from computing device 1100 (e.g., AC line power).

Computing device 1100 may include a display device 1103 (or corresponding interface circuitry, as discussed above). Display device 1103 may include any visual indicators, such as a heads-up display, a computer monitor, a projector, a touchscreen display, a liquid crystal display (LCD), a light-emitting diode display, or a flat panel display, for example.

Computing device 1100 may include an audio output device 1104 (or corresponding interface circuitry, as discussed above). Audio output device 1104 may include any device that generates an audible indicator, such as speakers, headsets, or earbuds, for example.

Computing device 1100 may include an audio input device 1110 (or corresponding interface circuitry, as discussed above). Audio input device 1110 may include any device that generates a signal representative of a sound, such as microphones, microphone arrays, or digital instruments (e.g., instruments having a musical instrument digital interface (MIDI) output).

Computing device 1100 may include a GPS device 1109 (or corresponding interface circuitry, as discussed above). GPS device 1109 may be in communication with a satellite-based system and may receive a location of computing device 1100, as known in the art.

Computing device 1100 may include other output device 1105 (or corresponding interface circuitry, as discussed above). Examples of the other output device 1105 may include an audio codec, a video codec, a printer, a wired or wireless transmitter for providing information to other devices, or an additional storage device.

Computing device 1100 may include other input device 1111 (or corresponding interface circuitry, as discussed above). Examples of the other input device 1111 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1100 may include a security interface device 1112. Security interface device 1112 may include any device that provides security measures for computing device 1100 such as intrusion detection, biometric validation, security encode or decode, access list management, malware detection, or spyware detection.

Computing device 1100, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1-11. The subject matter may be applied to other deposition applications, as well as any appropriate manufacturing application, as will be understood to those skilled in the art.

The following examples pertain to further embodiments, and specifics in the examples may be used anywhere in one or more embodiments.

Example 1 includes an IC die, comprising a plurality of varactor devices, wherein at least one varactor of the plurality of varactor devices comprises a first electrode, a second electrode, and a multi-layer stack of ferroelectric material (e.g., ferroelectric variable capacitance material) disposed between the first and second electrodes.

Example 2 includes the IC die of Example 1, wherein the ferroelectric material comprises hysteretic oxide material.

Example 3 includes the IC die of Example 2, wherein the multi-layer stack of hysteretic oxide material is formed as a ferroelectric superlattice.

Example 4 includes the IC die of Example 3, wherein the ferroelectric superlattice comprises alternated layers of wide band gap layers and narrow band gap layers.

Example 5 includes the IC die of any of Examples 1 to 4, wherein the first and second electrodes are arranged as parallel plate electrodes.

Example 6 includes the IC die of any of Examples 1 to 4, wherein the first and second electrodes are arranged as interdigitated electrodes.

Example 7 includes the IC die of any of Examples 1 to 6, further comprising front-side layers, and back-side layers, wherein the at least one varactor of the plurality of varactor devices is formed in the back-side layers.

Example 8 includes the IC die of Example 7, wherein the at least one varactor formed in the back-side layers is configured to operate as a diode.

Example 9 includes a system, comprising a substrate, a power supply, and an IC die attached to the substrate and coupled to the power supply, the IC die comprising a plurality of varactor devices, wherein at least one varactor of the plurality of varactor devices comprises a first electrode, a second electrode, and a multi-layer stack of ferroelectric material (e.g., ferroelectric variable capacitance material) disposed between the first and second electrodes.

Example 10 includes the system of Example 9, wherein the ferroelectric material comprises hysteretic oxide material.

Example 11 includes the system of Example 10, wherein the multi-layer stack of hysteretic oxide material is formed as a ferroelectric superlattice.

Example 12 includes the system of Example 11, wherein the ferroelectric superlattice comprises alternated layers of wide band gap layers and narrow band gap layers.

Example 13 includes the system of any of Examples 9 to 12, wherein the first and second electrodes are arranged as parallel plate electrodes.

Example 14 includes the system of any of Examples 9 to 12, wherein the first and second electrodes are arranged as interdigitated electrodes.

Example 15 includes the system of any of Examples 9 to 14, wherein the IC die further comprises front-side layers, and back-side layers, wherein the at least one varactor of the plurality of varactor devices is formed in the back-side layers.

Example 16 includes the system of Example 15, wherein the at least one varactor formed in the back-side layers is configured to operate as a diode.

Example 17 includes the system of any of Examples 9 to 16, further comprising a cooling structure operable to remove heat from the IC die to achieve an operating temperature at or below 0° C.

Example 18 includes the system of Example 17, wherein the IC die comprises a plurality of metallization layers over a front side of the plurality of varactor devices, the metallization layers to provide signal routing for the plurality of varactor devices, and wherein the cooling structure is over the plurality of metallization layers.

Example 19 includes the system of Example 18, wherein the cooling structure comprises a plurality of microchannels in the IC die and over the plurality of metallization layers, the microchannels to convey a heat transfer fluid therein.

Example 20 includes the system of Example 19, wherein the cooling structure further comprises a chiller mounted to the IC die over the microchannels, the chiller comprising one of a solid body comprising second microchannels to convey a second heat transfer fluid therein or a heat sink for immersion in a low-boiling point liquid.

Example 21 includes the system of any of Examples 17 to 20, wherein the cooling structure is operable to remove heat from the IC die to achieve an operating temperature at or below about −25° C.

Example 22 includes the system of any of Example 17 to 20, wherein the cooling structure is to convey liquid nitrogen to achieve an operating temperature at or below about −196° C.

Example 23 includes a method, comprising receiving a substrate, forming a first metallization layer over the substrate that includes a first electrode of a varactor device, forming a multi-layer stack of ferroelectric variable capacitance material over the first metallization layer, and forming a second metallization layer over the multi-layer stack of ferroelectric variable capacitance material, wherein the second metallization layer includes a second electrode of the varactor device on the multi-layer stack of ferroelectric variable capacitance material.

Example 24 includes the method of Example 23, wherein forming the multi-layer stack of ferroelectric variable capacitance material comprises forming the multi-layer stack of hysteretic oxide material.

Example 25 includes the method of Example 24, wherein forming the multi-layer stack of hysteretic oxide material comprises forming a ferroelectric superlattice of hysteretic oxide material.

Example 26 includes the method of Example 25, wherein forming the ferroelectric superlattice of hysteretic oxide material comprises alternating layers of wide band gap ferroelectric material and narrow band gap ferroelectric material to form the ferroelectric superlattice.

Example 27 includes the method of any of Examples 23 to 26, further comprising arranging the first and second electrodes as parallel plate electrodes.

Example 28 includes the method of any of Examples 23 to 26, further comprising arranging the first and second electrodes as interdigitated electrodes.

Example 29 includes the method of any of Examples 23 to 28, further comprising forming front-side layers on the substrate, forming back-side layers on the substrate, and forming the first metallization layer, the multi-layer stack of ferroelectric variable capacitance material, and the second metallization layer in the back-side layers.

Example 30 includes the method of Example 29, further comprising configuring the first metallization layer, the multi-layer stack of ferroelectric variable capacitance material, and the second metallization layer formed in the back-side layers to operate as a diode.

Example 31 includes the method of any of Examples 23 to 30, further comprising forming a cooling structure over the first and second metallization layers, wherein the cooling structure is operable to remove heat from the varactor device to achieve an operating temperature at or below 0° C.

Example 32 includes an apparatus, comprising means for receiving a substrate, means for forming a first metallization layer over the substrate that includes a first electrode of a varactor device, means for forming a multi-layer stack of ferroelectric variable capacitance material over the first metallization layer, and means for forming a second metallization layer over the multi-layer stack of ferroelectric variable capacitance material, wherein the second metallization layer includes a second electrode of the varactor device on the multi-layer stack of ferroelectric variable capacitance material.

Example 33 includes the apparatus of Example 32, wherein the means for forming the multi-layer stack of ferroelectric variable capacitance material comprises means for forming the multi-layer stack of hysteretic oxide material.

Example 34 includes the apparatus of Example 33, wherein the means for forming the multi-layer stack of hysteretic oxide material comprises means for forming a ferroelectric superlattice of hysteretic oxide material.

Example 35 includes the apparatus of Example 34, wherein the means for forming the ferroelectric superlattice of hysteretic oxide material comprises means for alternating layers of wide band gap ferroelectric material and narrow band gap ferroelectric material to form the ferroelectric superlattice.

Example 36 includes the apparatus of any of Examples 32 to 35, further comprising means for arranging the first and second electrodes as parallel plate electrodes.

Example 37 includes the apparatus of any of Examples 32 to 35, further comprising means for arranging the first and second electrodes as interdigitated electrodes.

Example 38 includes the apparatus of any of Examples 32 to 37, further comprising means for forming front-side layers on the substrate, means for forming back-side layers on the substrate, and means for forming the first metallization layer, the multi-layer stack of ferroelectric variable capacitance material, and the second metallization layer in the back-side layers.

Example 39 includes the apparatus of Example 38, further comprising means for configuring the first metallization layer, the multi-layer stack of ferroelectric variable capacitance material, and the second metallization layer formed in the back-side layers to operate as a diode.

Example 40 includes the apparatus of any of Examples 32 to 39, further comprising means for forming a cooling structure over the first and second metallization layers, wherein the cooling structure is operable to remove heat from the varactor device to achieve an operating temperature at or below 0° C.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An integrated circuit (IC) die, comprising a plurality of varactor devices, wherein at least one varactor of the plurality of varactor devices comprises:
a first electrode;
a second electrode; and
a multi-layer stack of ferroelectric material disposed between the first and second electrodes.

2. The IC die of claim 1, wherein the ferroelectric material comprises hysteretic oxide material.

3. The IC die of claim 2, wherein the multi-layer stack of hysteretic oxide material is formed as a ferroelectric superlattice.

4. The IC die of claim 3, wherein the ferroelectric superlattice comprises alternated layers of wide band gap layers and narrow band gap layers.

5. The IC die of claim 1, wherein the first and second electrodes are arranged as parallel plate electrodes.

6. The IC die of claim 1, wherein the first and second electrodes are arranged as interdigitated electrodes.

7. A system, comprising:
a substrate;
a power supply; and
an integrated circuit (IC) die attached to the substrate and coupled to the power supply, the IC die comprising a plurality of varactor devices, wherein at least one varactor of the plurality of varactor devices comprises:
a first electrode;
a second electrode; and
a multi-layer stack of ferroelectric material disposed between the first and second electrodes.

8. The system of claim 7, wherein the ferroelectric material comprises hysteretic oxide material.

9. The system of claim 8, wherein the multi-layer stack of hysteretic oxide material is formed as a ferroelectric superlattice.

10. The system of claim 9, wherein the ferroelectric superlattice comprises alternated layers of wide band gap layers and narrow band gap layers.

11. The system of claim 7, wherein the first and second electrodes are arranged as parallel plate electrodes.

12. The system of claim 7, wherein the first and second electrodes are arranged as interdigitated electrodes.

13. The system of claim 7, wherein the IC die further comprises:
front-side layers; and
back-side layers, wherein the at least one varactor of the plurality of varactor devices is formed in the back-side layers.

14. The system of claim 13, wherein the at least one varactor formed in the back-side layers is configured to operate as a diode.

15. The system of claim 7, further comprising:
a cooling structure operable to remove heat from the IC die to achieve an operating temperature at or below 0° C.

16. A method, comprising:
receiving a substrate;
forming a first metallization layer over the substrate that includes a first electrode of a varactor device;
forming a multi-layer stack of ferroelectric variable capacitance material over the first metallization layer; and
forming a second metallization layer over the multi-layer stack of ferroelectric variable capacitance material, wherein the second metallization layer includes a second electrode of the varactor device on the multi-layer stack of ferroelectric variable capacitance material.

17. The method of claim 16, wherein forming the multi-layer stack of ferroelectric variable capacitance material comprises:
forming the multi-layer stack of hysteretic oxide material.

18. The method of claim 17, wherein forming the multi-layer stack of hysteretic oxide material comprises:
forming a ferroelectric superlattice of hysteretic oxide material.

19. The method of claim 16, further comprising:
arranging the first and second electrodes as one of parallel plate electrodes and interdigitated electrodes.

20. The method of claim 16, further comprising:
forming front-side layers on the substrate;
forming back-side layers on the substrate; and
forming the first metallization layer, the multi-layer stack of ferroelectric variable capacitance material, and the second metallization layer in the back-side layers to operate as a diode.
